(19) United States
(12) Patent Application Publication
(10) Pub. No.: US 2015/0206574 A1
(43) Pub. Date: Jul. 23, 2015

(54) RELOCATING INFREQUENTLY-ACCESSED DYNAMIC RANDOM ACCESS MEMORY (DRAM) DATA TO NON-VOLATILE STORAGE

(71) Applicant: Advanced Micro Devices, Inc., Sunnyvale, CA (US)

(72) Inventors: Joseph L. Greathouse, Austin, TX (US); Ciji Isen, Austin, TX (US); Mitesh Meswani, Austin, TX (US)

(73) Assignee: Advanced Micro Devices, Inc., Sunnyvale, CA (US)

(21) Appl. No.: 14/160,618

(22) Filed: Jan. 22, 2014

(51) Int. Cl. G11C 11/406; G11C 14/00

(52) U.S. Cl. CPC G11C 11/40615; G11C 14/0018

(57) ABSTRACT

A method includes emptying a first region of a dynamic random access memory of data by moving data from the first region to a non-volatile memory and reducing a refresh rate of the dynamic random access memory responsive to emptying the first region of data. A system includes a memory controller to refresh a dynamic random access memory based on a configurable refresh rate, the dynamic random access memory having a plurality of regions, each region having an associated minimum refresh rate, and a processing unit to empty a first region of the plurality of regions of the dynamic random access memory by moving data from the first region to a non-volatile memory and to reduce the configurable refresh rate responsive to emptying the first region.

### BACKGROUND

1. Field of the Disclosure

This application relates generally to processing systems, and, more particularly, to data storage in data processing systems.

2. Description of the Related Art

Processing systems use memory to store data for later use. For example, processing devices such as central processing units (CPUs), graphics processing units (GPUs), and accelerated processing units (APUs) can read data from memory, perform operations using the data, and then write the results back into the memory. Processing systems can implement different types of memory to store information. For example, non-volatile memory can be used for long-term storage of information because non-volatile memory retains information even when power is not supplied to the memory elements. In contrast, volatile memory requires a constant supply of power to retain information.

Dynamic random access memory (DRAM) is a form of volatile memory that requires periodic re-writing, or “refreshing”, of the DRAM cells to retain information stored in the DRAM cells. Refreshing DRAM cells consumes energy, since the amplification circuitry and each read and write command from the memory controller uses power. Additionally, while a memory controller is refreshing a line, it is unable to send other commands to that region of the DRAM, thereby reducing the aggregate performance of the memory system, since regular loads and stores cannot complete until the refresh has finished. As DRAM scales to smaller feature sizes, manufacturers are shipping devices that can hold increasing amounts of data, so more lines are included in devices of each generation. However, the refresh times and write times on such DRAMs are not scaling at the same rate as the number of lines. As a result, the percentage of time that a memory controller spends refreshing the attached memory has increased as more and denser DRAM is added to the processing system. This load on the memory system can significantly affect the performance of the processing system, since significant time intervals are required to service refreshes rather than useful requests from the processing elements. Additionally, as the number of refreshes per second increases, the power used refreshing the memory (rather than servicing useful requests) increases. Because leakage is a physical process, some DRAM cells lose their charge faster than others. However, rather than refreshing each line of a DRAM at a rate corresponding to its leakage rate, conventional memory systems refresh all lines in the DRAM at the same rate, and thus, power is wasted and performance is degraded by needlessly refreshing cells.

### BRIEF DESCRIPTION OF THE DRAWINGS

The present disclosure may be better understood, and its numerous features and advantages made apparent to those skilled in the art, by referencing the accompanying drawings. The use of the same reference symbols in different drawings indicates similar or identical items.

FIG. 1 is a block diagram of a processing system that relocates cold dynamic random access memory (DRAM) data to non-volatile storage in accordance with some embodiments.

FIG. 2 is a flow diagram of an example method for relocating cold DRAM data to non-volatile storage in accordance with some embodiments

FIGS. 3-5 are diagrams of a DRAM illustrating regions having different refresh rates and the movement of data in the regions in accordance with some embodiments.

FIG. 6 is a flow diagram of an example method for the design and fabrication of an IC device implementing one or more aspects in accordance with some embodiments.

### DETAILED DESCRIPTION

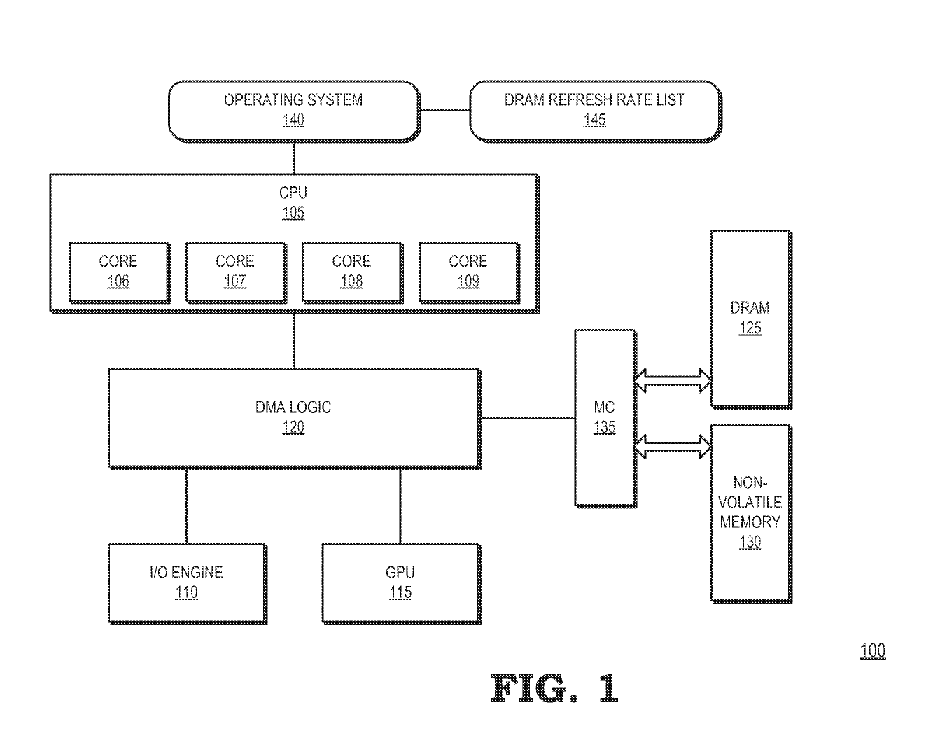

FIGS. 1-6 describe embodiments of a memory system that removes infrequently-accessed, or “cold,” dynamic random access memory (DRAM) lines (also referred to in the art as “pages”) from regions of the DRAM to allow a refresh rate of the DRAM to be reduced. Lines in the DRAM may be distinguished from one another based on their minimum refresh rates. Due to physical differences in the DRAM cells, each line has unique leakage characteristics that determine the minimum rate at which the line must be refreshed to maintain the integrity of the data stored therein.

Cold DRAM lines having higher refresh rates relative to other DRAM lines may be moved to non-volatile memory (e.g., a magnetic disk or flash memory), a process referred to herein as “swapping.” Swapping the data from the DRAM lines with higher refresh rates to the non-volatile memory allows the memory system to reduce the overall refresh rate of the DRAM without sacrificing data integrity or performance, thereby conserving power and increasing memory utilization for useful data transfers as opposed to refresh activities. In some embodiments, DRAM lines that are frequently (i.e., non-infrequently) accessed, or “not cold”, may be relocated from a higher refresh rate region to a lower refresh rate region. This relocation may be implemented by exchanging cold data with data that is not cold in different refresh rate regions or by moving data that is not cold from a high refresh rate region to a lower refresh region as space permits. Because the swapped data is no longer available in the DRAM, latency may be generated in the system if the data is later requested, as it must be retrieved from the generally slower, non-volatile memory. Selecting cold data for swapping to the non-volatile memory reduces the likelihood that the data will be requested at a later time.

FIG. 1 is a block diagram of a processing system 100 in accordance with some embodiments. In various embodiments, the processing system 100 may be a personal computer, a laptop computer, a handheld computer, a tablet computer, a mobile device, a telephone, a personal data assistant (“PDA”), a server, a mainframe, a work terminal, a music player, a smart television, a game console, and the like. To the extent certain example aspects of the processing system 100 are not described herein, such example aspects may or may not be included in various embodiments without limiting the spirit and scope of the embodiments of the present application as would be understood by one of skill in the art.

The processing system 100 includes a central processing unit (CPU) 105 for executing instructions. Some embodiments of the CPU 105 include multiple processor cores 106-109 that can execute instructions independently, concurrently, and/or in parallel. The CPU 105 shown in FIG. 1 includes four processor cores 106-109. Some embodiments of the CPU 105 may include more or fewer than the four processor cores 106-109 shown in FIG. 1. The processing system 100 also includes an input/output engine 110 for handling input or output operations associated with elements of the processing system such as keyboards, mice, printers, external disks, and the like. A graphics processing unit (GPU) 115 is also included in the processing system 100 for creating visual images intended for output to a display. Some embodiments of the GPU 115 may include multiple processor cores (not shown).

The processing system 100 shown in FIG. 1 also includes direct memory access (DMA) logic 120 for generating addresses and initiating memory read or write cycles. The CPU 105 may initiate transfers between memory elements in the processing system 100 (such as DRAM memory 125 and non-volatile memory 130 (e.g., flash memory or hard disk storage) and/or entities connected to the DMA logic 120 including the CPU 105, the I/O engine 110, and the GPU 115. Some embodiments of the DMA logic 120 may also be used for memory-to-memory data transfer or transferring data between the cores 106-109. The CPU 105 can perform other operations concurrently with the data transfers being performed by the DMA logic 120 which may provide an interrupt to the CPU 105 to indicate that the transfer is complete.

A memory controller (MC) 135 may be used to coordinate the flow of data between the DMA logic 120, the DRAM 125, and the non-volatile memory 130. The memory controller 135 includes logic used to control reading from and writing to the memories 125, 130. The memory controller 135 may also include refresh logic that is used to periodically re-write information to the DRAM 125 so that information in the memory cells of the DRAM 125 is retained. The memory controller 135 supports a variable refresh rate for the DRAM 125.

The operation of the processing system 100 is generally controlled by an operating system 140 including software that interfaces with the various elements of the processing system 100. In some embodiments, the operating system 140 employs a virtual memory system that allows executing processes (e.g., software applications) to each exist within its own self-contained memory space. Such a virtual memory technique allows the processes to see more system memory than actually exists in the physical system. When these processes attempt to use more memory than physically exists in the system, the operating system 140 swaps some of the existing data into a secondary storage location such as the non-volatile memory 130 to make room for the incoming data. Thus, the operating system 140 selects what data is to be stored in the DRAM 125 to support executing processes and also selects which data in the DRAM 125 is to be swapped to the non-volatile memory 130.

In general, the operating system 140 selects cold DRAM lines to swap to the non-volatile memory 130. A cold line may be identified based on an activity threshold. For example, if the number of access for a given line divided by the total number of accesses falls below a predetermined threshold, the line may be designated by the operating system 140 as a cold line. In conjunction with this general approach, the operating system 140 also makes swapping decisions based on the refresh characteristics of the DRAM 125. To facilitate cold line swapping and refresh rate control, the operating system 140 maintains a DRAM refresh rate list 145 that allows it to identify various refresh rate regions in the DRAM 145. In some embodiments, the DRAM refresh rate list 145 may be stored in the DRAM 125 for use by the operating system 140. Using the DRAM refresh rate list 145, the operating system 140 selects cold data residing in high refresh rate regions and swaps the data to the non-volatile memory 130. The operating system 140 configures the refresh rate of the memory controller 135 based on the presence or absence of data in the high refresh rate region. If all of the data is removed from the high refresh rate region, the operating system 140 may send an instruction through the CPU 105 to the memory controller 135 to reduce the refresh rate.

To further facilitate the removal of data from high refresh rate regions of the DRAM 125, the operating system 140 may also elect to move data that is not cold from higher refresh rate regions to lower refresh rate regions. This reallocation of the data in the DRAM 125 serves to empty a higher refresh rate region so that the refresh rate can be reduced. In some embodiments, the cold data in a low refresh rate data region may be exchanged for data that is not cold but is stored in a high refresh rate region. Thus, when it is feasible to empty an entire region to allow the refresh rate to be decreased, only cold data will populate the region. In this manner, the operating system 140 can delay swapping out the cold data until doing so allows it to lower the refresh rate, i.e., it can empty the entire region. If the cold data is requested prior to its being swapped to the non-volatile memory 135 to empty the region, a retrieval delay will be avoided, thereby improving performance. Thus, the operating system 140 does not indiscriminately swap cold data, but rather, swaps the cold data when it makes it possible to reduce the refresh rate.

The organization and granularity of the DRAM refresh rate list 145 may vary. In some embodiments, the operating system 140 may track a refresh rate for each line in the DRAM 125. In some embodiments, the DRAM refresh rate list 145 may define a refresh rate region and a list of lines or line ranges that fall into that region. In general, the refresh rate for a given DRAM line 125 is the minimum frequency at which the line must be refreshed to maintain the integrity of the data stored therein. The minimum refresh rate may be determined by running a test pattern through the DRAM 125 (more than one line 125 may be characterized at a time) at a relatively high refresh rate. If data integrity is maintained, the refresh rate is higher than the minimum. Multiple tests may be performed while iteratively decreasing the refresh rate to determine the point at which data corruption is observed. The minimum refresh rate is a rate just higher than that at which corruption is observed. A margin may be provided in the minimum refresh rate to account for test variation and component aging effects that might increase leakage over time as the DRAM 125 ages. The minimum refresh rate may be determined at any desired level of granularity, such as for regions of the DRAM 125 or for each individual line.

The information in the DRAM refresh rate list 145 regarding the refresh rates of the DRAM lines 125 may be generated during an initialization or boot process of the processing system 100 or it may be generated offline. For example, a memory test conducted during initialization may vary the refresh rate to identify the minimum refresh rate for each line or region. The initialization routine may set the refresh rate at the level associated with low refresh rate regions. The memory test identifies the lines in the DRAM 125 that operate properly using this refresh rate. Lines that require a higher refresh rate will exhibit data corruption. The initialization routine may then set the refresh rate to the level associated with medium refresh rate regions and repeat the process to identify the lines that operate properly. This approach may be repeated for whatever number of refresh rate grades that the operating system 140 employs. In another example, the refresh rate characteristics of the DRAM 125 may be determined offline using a test unit (not shown). The refresh rate data may be stored in a memory structure in the DRAM 125 that the operating system 140 reads during system initialization to populate the DRAM refresh rate list 145.

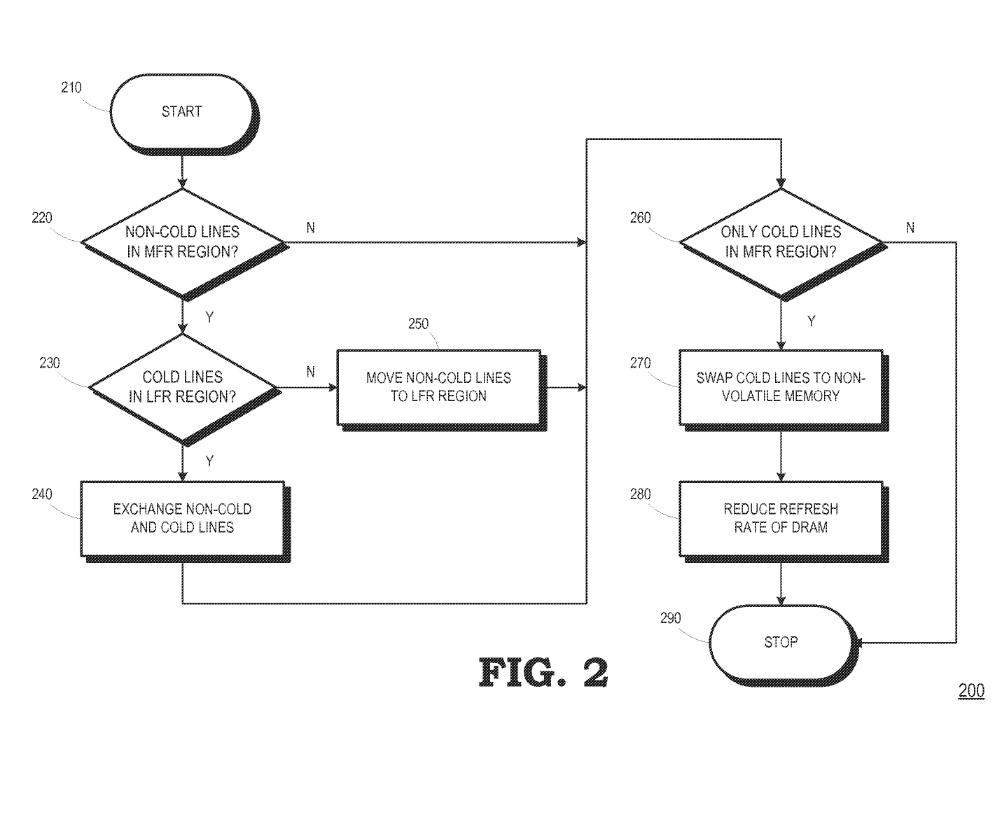

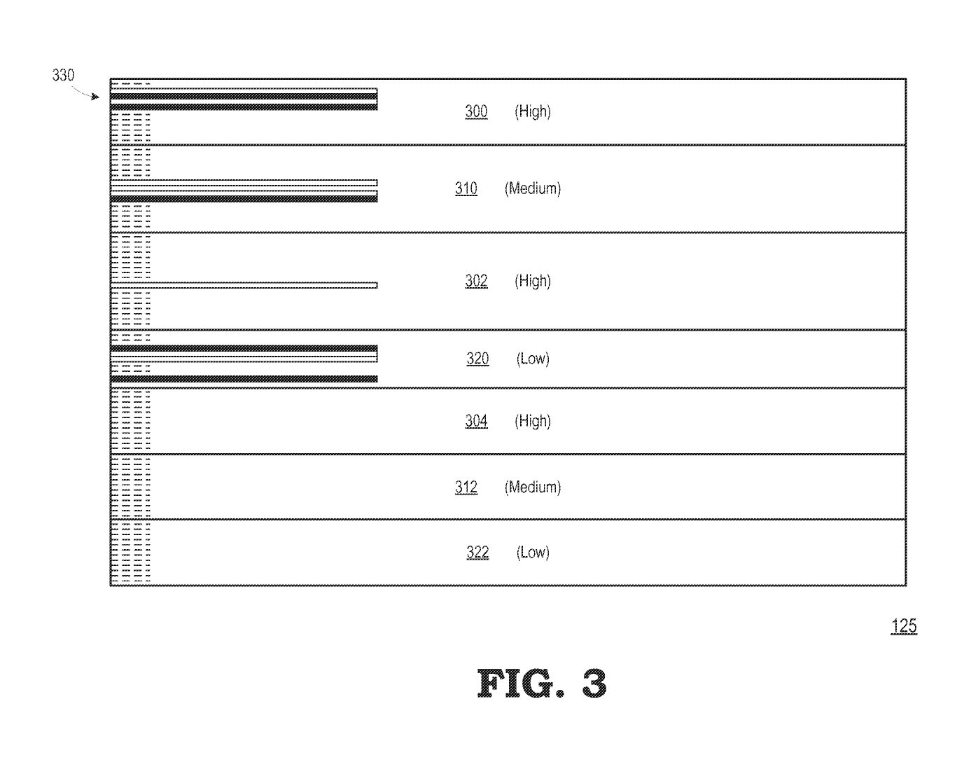

FIG. 2 is a flow diagram of a method 200 for relocating cold DRAM data to non-volatile storage in accordance with some embodiments. The method 200 is described with reference to FIGS. 3-5, which illustrate different refresh rate regions of the DRAM 125 in accordance with some embodiments. As illustrated in FIG. 3, the DRAM 135 includes high refresh rate regions 300, 302, 304, medium refresh rate regions 310, 312, and low refresh rate regions 320, 322. Each region 300, 302, 304, 310, 312, 320, 322 stores one or more DRAM lines 330. In FIG. 3, lines 330 that are solid represent cold lines and lines 330 that are not solid represent lines that are not cold. The operating system 140 may track the status of the lines 330 in a data structure, such as a data table stored in the DRAM 145. The operating system 140 may identify cold lines based on an activity threshold, where the line status, Line_{STATUS}, is COLD if the number of accesses for the line, ACC_{LINE}, divided by the total number of memory accesses. ACC_{TOTAL}, in a given time period is less than a predetermined threshold, Activitv_Threshold.

$${Line}_{Status} = COLD if \frac{{ACC}_{LINE}}{{ACC}_{TOTAL}} < Activity\_Threshold$$

For ease of illustration, only a sample of the lines 330 stored in the DRAM 125 is illustrated. The lines 330 do not extend completely across the regions 300 to avoid obscuring the reference labels, not to imply that there is unused space remaining in the lines. The operating system 140 may use the information stored in the DRAM refresh rate list 145 to delineate the various regions 300, 302, 304, 310, 312, 320, 322. The number of refresh grades (e.g., high, medium, low) defined for the regions 300, 302, 304, 310, 312, 320, 322 may differ from the example illustrated in FIG. 3. For purposes of the illustration discussed in reference to FIG. 3, it is assumed that the operating system 140 uses three refresh rate grades.

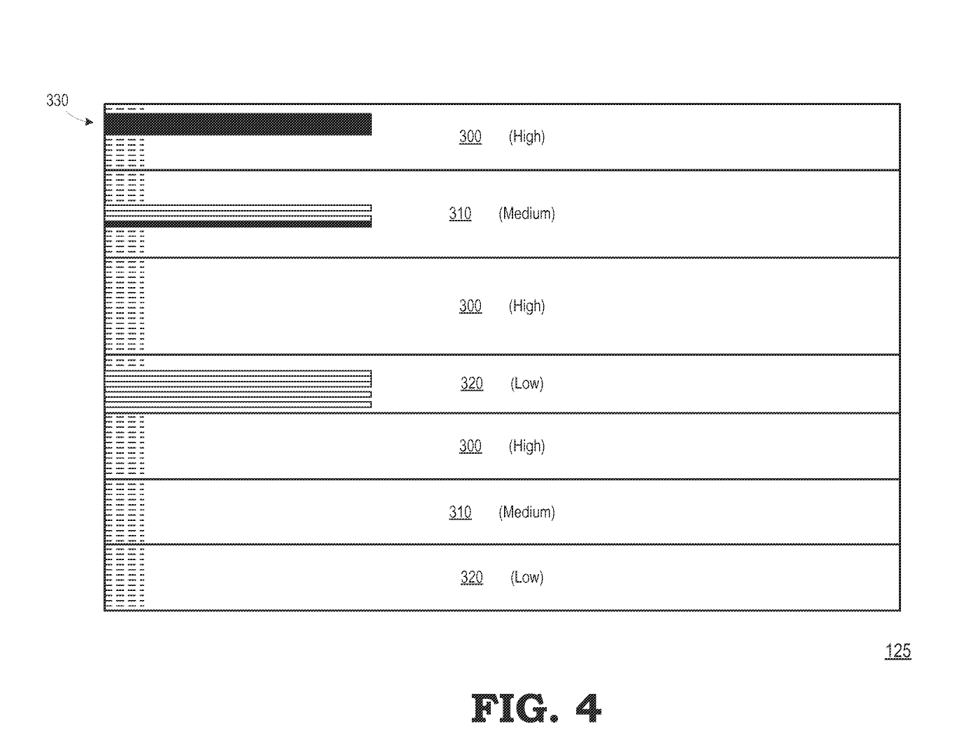

The method of FIG. 2 may be applied to any number of refresh rate regions, such as the regions 300, 302, 304, 310, 312, 320, 322 illustrated in FIG. 3. The method 200 starts in method block 210. In method block 220, the operating system 140 determines if lines that are not cold are disposed in a more frequently refreshed region (“MFR region”). Referring to FIG. 3, the non-solid lines in the high refresh rate region 300 represent lines that are not cold, and the sold lines represent lines that are cold. In method block 230, the operating system 140 determines if cold lines are present in a less frequently refreshed region (“LFR region”), such as the solid lines in the low refresh rate region 320. If the conditions of method blocks 220 and 230 are met, the operating system 140 exchanges the non-cold and cold lines in method block 240. FIG. 4 illustrates the DRAM 125 after this exchange in accordance with some embodiments. The cold lines are moved to the high refresh rate region 300, and the non-cold lines are moved to the low refresh rate region 320.

In some embodiments, the operating system 140 may move non-cold lines out of a high refresh rate region 300 even if there are no cold lines with which to exchange them. If there are non-cold lines in a MRF region in method block 220, but no cold lines in an LFR region in method block 230, the operating system 140 may move the non-cold lines to an LFR region 320, 322 in method block 250, assuming there is room (an empty line). For example, the non-cold line in high refresh rate region 302 shown in FIG. 3 may be moved to the low refresh rate region 320, as shown in FIG. 4.

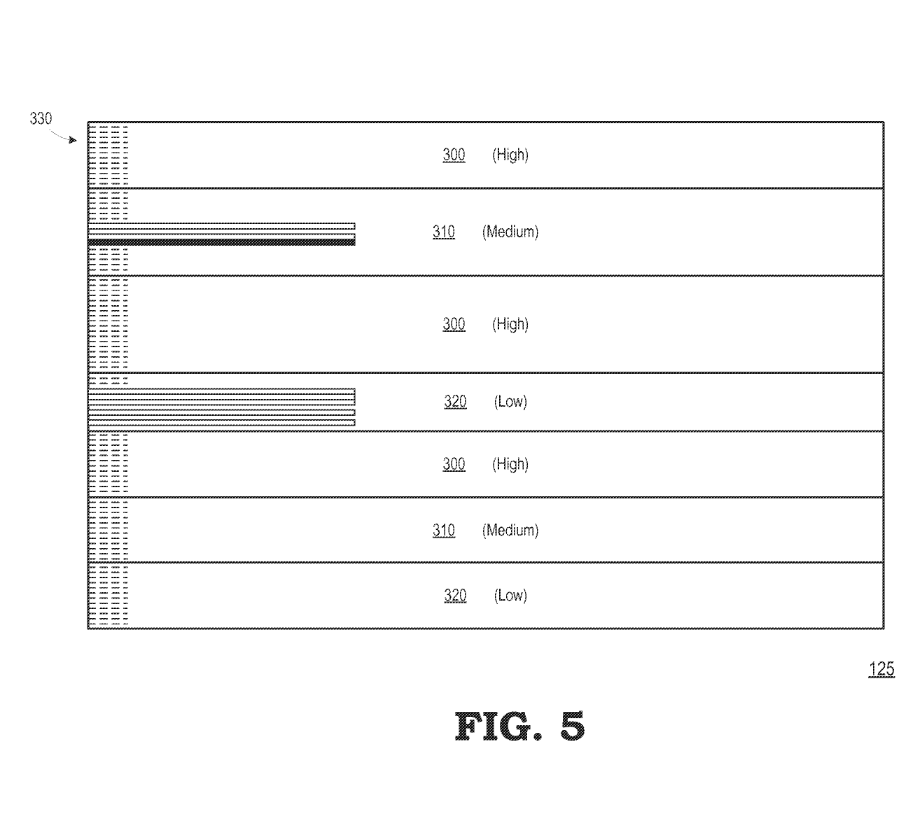

After the moves in method blocks 240 or 250, or if there are no exchanges candidates identified in method block 220, the operating system 140 determines if only cold lines exist in an MRF region in method block 260. As seen in FIG. 4, the high refresh rate region 300 includes only cold lines. In this example, it is assumed that the other high refresh rate regions 302, 304, for which individual lines 330 are not illustrated, are either empty or also contain only cold lines. Responsive to the high refresh rate region 300 containing only cold lines in method block 260, the operating system 140 swaps the cold lines to the non-volatile memory 130 in method block 270, as illustrated in FIG. 5.

Because the high refresh rate regions 300 are now empty, the operating system configures the memory controller 135 of FIG. 1 to reduce the refresh rate applied to the DRAM 125 in method block 280, and the method 200 ends in method block 290. Reducing the refresh rate of the DRAM 125 conserves power and also increases the bandwidth of the memory controller 135 for handling productive read and write transactions in the DRAM 125.

If the computational activity level of the processing system 100 is high, such as with a high performance computing application, it may be likely that there are no empty lines in one of the LFR regions to allow movements under method block 250. In such a case, the operating system 140 waits until cold pages are present in the LFR region to allow exchanges in method block 240. Once enough cold pages have been exchanged, the MFR region may be emptied of non-cold lines, allowing the operating system 140 to swap the cold lines to the non-volatile memory 130 and reduce the refresh rate. Because the cold lines store, by definition, infrequently-accessed data, the performance of the processing system 100 is not significantly impacted if such lines have to be later retrieved from the non-volatile memory 130.

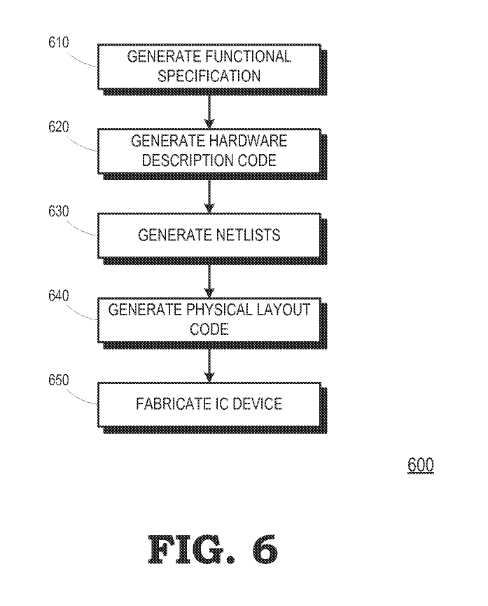

Note that a cold line remains in the medium refresh rate region 310. If a memory request is received for the cold line in medium rate region 310 it may be serviced without incurring a retrieval delay. Since the high refresh rate regions 300, 302, 304 are emptied (see FIG. 6), and the refresh rate is reduced, the medium refresh rate regions 310, 312 now become the MFR regions with respect to the method of FIG. 2. The operating system 140 may repeat the method 200 and attempt to store only cold lines in the medium refresh rate regions 310, 312. For example, if cold lines exist in a low refresh rate region 320, 322, they may be exchanged with the non-cold lines in method block 240, or they may be moved to low refresh rate regions 320, 322 if there is room. Once the medium refresh rate regions 320, 322 have been arranged to store only cold data, the cold data may be swapped to the non-volatile memory 130, and the refresh rate may be further reduced. The operating system 140 may also consider the multiple refresh grade regions in parallel, and empty both the high refresh rate regions 300, 302, 304 and the medium refresh rate regions 310, 312 during the same iteration of the method 200. As discussed above, more than three levels of refresh rate regions may be defined, allowing finer granularity in the refresh rate control.

In some embodiments, at least some of the functionality described above may be implemented by one or more processors executing one or more software programs tangibly stored at a computer readable medium, and whereby the one or more software programs comprise instructions that, when executed, manipulate the one or more processors to perform one or more functions of the processing system described above. Further, in some embodiments, serial data interfaces described above are implemented with one or more integrated circuit (IC) devices (also referred to as integrated circuit chips). Electronic design automation (EDA) and computer aided design (CAD) software tools may be used in the design and fabrication of these IC devices. These design tools typically are represented as one or more software programs. The one or more software programs comprise code executable by a processing system to manipulate the processing system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any non-transitory storage medium, or combination of storage media, accessible by a processing system during use to provide instructions and/or data to the processing system. Such storage media can include, but are not limited to, optical media (e.g., compact disc (CD), digital versatile disc (DVD), or Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the processing system via a wired or wireless network (e.g., network accessible storage (NAS)).

FIG. 6 is a flow diagram illustrating an example method 600 for the design and fabrication of an IC device implementing one or more aspects in accordance with some embodiments. As noted above, the code generated for each of the following processes is stored or otherwise embodied in computer readable storage media for access and use by the corresponding design tool or fabrication tool.

At block 610 a functional specification for the IC device is generated. The functional specification (often referred to as a micro architecture specification (MAS)) may be represented by any of a variety of programming languages or modeling languages, including C, C++, SystemC, Simulink, or MATLAB.

At block 620, the functional specification is used to generate hardware description code representative of the hardware of the IC device. In some embodiments, the hardware description code is represented using at least one Hardware Description Language (HDL), which comprises any of a variety of computer languages, specification languages, or modeling languages for the formal description and design of the circuits of the IC device. The generated HDL code typically represents the operation of the circuits of the IC device, the design and organization of the circuits, and tests to verify correct operation of the IC device through simulation. Examples of HDL include Analog HDL (AHDL), Verilog HDL, SystemVerilog HDL, and VHDL. For IC devices implementing synchronized digital circuits, the hardware descriptor code may include register transfer level (RTL) code to provide an abstract representation of the operations of the synchronous digital circuits. For other types of circuitry, the hardware descriptor code may include behavior-level code to provide an abstract representation of the circuitry's operation. The HDL model represented by the hardware description code typically is subjected to one or more rounds of simulation and debugging to pass design verification.

After verifying the design represented by the hardware description code, at block 630 a synthesis tool is used to synthesize the hardware description code to generate code representing or defining an initial physical implementation of the circuitry of the IC device. In some embodiments, the synthesis tool generates one or more netlists comprising circuit device instances (e.g., gates, transistors, resistors, capacitors, inductors, diodes, etc.) and the nets, or connections, between the circuit device instances. Alternatively, all or a portion of a netlist can be generated manually without the use of a synthesis tool. As with the hardware description code, the netlists may be subjected to one or more test and verification processes before a final set of one or more netlists is generated.

Alternatively, a schematic editor tool can be used to draft a schematic of circuitry of the IC device and a schematic capture tool then may be used to capture the resulting circuit diagram and to generate one or more netlists (stored on a computer readable media) representing the components and connectivity of the circuit diagram. The captured circuit diagram may then be subjected to one or more rounds of simulation for testing and verification.

At block 640, one or more EDA tools use the netlists produced at block 630 to generate code representing the physical layout of the circuitry of the IC device. This process can include, for example, a placement tool using the netlists to determine or fix the location of each element of the circuitry of the IC device. Further, a routing tool builds on the placement process to add and route the wires needed to connect the circuit elements in accordance with the netlist(s). The resulting code represents a three-dimensional model of the IC device. The code may be represented in a database file format, such as, for example, the Graphic Database System II (GDSII) format. Data in this format typically represents geometric shapes, text labels, and other information about the circuit layout in hierarchical form.

At block 650, the physical layout code (e.g., GDSII code) is provided to a manufacturing facility, which uses the physical layout code to configure or otherwise adapt fabrication tools of the manufacturing facility (e.g., through mask works) to fabricate the IC device. That is, the physical layout code may be programmed into one or more processing systems, which may then control, in whole or part, the operation of the tools of the manufacturing facility or the manufacturing operations performed therein.

As disclosed herein, in some embodiments a method includes emptying a first region of a dynamic random access memory of data by moving data from the first region to a non-volatile memory and reducing a refresh rate of the dynamic random access memory responsive to emptying the first region of data.

As disclosed herein, in some embodiments a system includes a memory controller to refresh a dynamic random access memory based on a configurable refresh rate, the dynamic random access memory having a plurality of regions, each region having an associated minimum refresh rate, and a processing unit to empty a first region of the plurality of regions of the dynamic random access memory by moving data from the first region to a non-volatile memory and to reduce the configurable refresh rate responsive to emptying the first region.

As disclosed herein, in some embodiments a system includes a memory controller to refresh a dynamic random access memory based on a configurable refresh rate, the dynamic random access memory having a plurality of regions, each region having an associated minimum refresh rate, and a processing unit to exchange infrequently-accessed data in a first region of the plurality of regions having a first minimum refresh rate with non-infrequently-accessed data in a second region of the plurality of regions having a second minimum refresh rate higher than the first minimum refresh rate, to move the data in the second region to a non-volatile memory responsive to the second region storing only infrequently-accessed data, and to reduce the configurable refresh rate to a first value less than the second minimum refresh rate responsive to emptying the first region.

As disclosed herein, in some embodiments a non-transitory computer readable media stores code to adapt at least one computer system to perform a portion of a process to fabricate at least part of a system. The system includes a memory controller to refresh a dynamic random access memory based on a configurable refresh rate, the dynamic random access memory having a plurality of regions, each region having an associated minimum refresh rate, and a processing unit to empty a first region of the plurality of regions of the dynamic random access memory by moving data from the first region to a non-volatile memory and to reduce the configurable refresh rate responsive to emptying the first region.

As disclosed herein, in some embodiments a non-transitory computer readable media stores code to adapt at least one computer system to perform a portion of a process to fabricate at least part of a system. The system includes a memory controller to refresh a dynamic random access memory based on a configurable refresh rate, the dynamic random access memory having a plurality of regions, each region having an associated minimum refresh rate, and a processing unit to exchange infrequently-accessed data in a first region of the plurality of regions having a first minimum refresh rate with non-infrequently-accessed data in a second region of the plurality of regions having a second minimum refresh rate higher than the first minimum refresh rate, to move the data in the second region to a non-volatile memory responsive to the second region storing only infrequently-accessed data, and to reduce the configurable refresh rate to a first value less than the second minimum refresh rate responsive to emptying the first region.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed.

Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

What is claimed is:

1. A method, comprising:
emptying a first region of a dynamic random access memory of data by moving data from the first region to a non-volatile memory; and
reducing a refresh rate of the dynamic random access memory responsive to emptying the first region of data.

2. The method of claim 1, wherein moving the data comprises:
identifying infrequently-accessed data in the first region; and
moving the infrequently-accessed data to the non-volatile memory to empty to the first region of data.

3. The method of claim 2, further comprising:
exchanging infrequently-accessed data in a second region of the dynamic random access memory for non-infrequently-accessed data in the first region, wherein the first region has a higher minimum refresh rate than the second region.

4. The method of claim 2, further comprising:
moving non-infrequently-accessed data in the first region to a second region of the dynamic random access memory, wherein the first region has a higher minimum refresh rate than the second region.

5. The method of claim 4, further comprising:
emptying the second region by moving data from the second region to the non-volatile memory; and
further reducing the refresh rate of the dynamic random access memory responsive to emptying the second region of data.

6. The method of claim 1, wherein moving the data further comprises:
moving the data responsive to the first region storing only infrequently-accessed data.

7. The method of claim 1, wherein reducing the refresh rate further comprises reducing the refresh rate below a minimum refresh rate associated with the first region.

8. The method of claim 1, wherein the non-volatile memory comprises a hard disk.

9. A system, comprising:
a memory controller to refresh a dynamic random access memory based on a configurable refresh rate, the dynamic random access memory having a plurality of regions, each region having an associated minimum refresh rate; and
a processing unit to empty a first region of the plurality of regions of the dynamic random access memory by moving data from the first region to a non-volatile memory and to reduce the configurable refresh rate responsive to emptying the first region.

10. The system of claim 9, wherein the processing unit further is to:
identify infrequently-accessed data in the first region and moves the infrequently-accessed data to the non-volatile memory to empty to the first region of data.

11. The system of claim 10, wherein the processing unit further is to:
exchange infrequently-accessed data in a second region of the dynamic random access memory for non-infrequently-accessed data in the first region, wherein the first region has a higher minimum refresh rate than the second region.

12. The system of claim 10, wherein the processing unit further is to:
move non-infrequently-accessed data in the first region to a second region of the dynamic random access memory, wherein the first region has a higher minimum refresh rate than the second region.

13. The system of claim 12, wherein the processing unit further is to:
move data from the second region to the non-volatile memory to empty the second region of data and further reduce the configurable refresh rate responsive to emptying the second region of data.

14. The system of claim 9, wherein the processing unit further is to:
move the data responsive to the first region storing only infrequently-accessed data.

15. The system of claim 9, wherein the processing unit further is to:
reduce the refresh rate below a minimum refresh rate associated with the first region.

16. The system of claim 9, further comprising:
a non-transitory computer readable medium to store a set of executable instructions, the set of executable instructions to manipulate the processing unit to empty the first region and to reduce the configurable refresh rate.

17. A system, comprising:
a memory controller to refresh a dynamic random access memory based on a configurable refresh rate, the dynamic random access memory having a plurality of regions, each region having an associated minimum refresh rate; and
a processing unit to exchange infrequently-accessed data in a first region of the plurality of regions having a first minimum refresh rate with non-infrequently-accessed data in a second region of the plurality of regions having a second minimum refresh rate higher than the first minimum refresh rate, to move the data in the second region to a non-volatile memory responsive to the second region storing only infrequently-accessed data, and to reduce the configurable refresh rate to a first value less than the second minimum refresh rate responsive to emptying the first region.

18. The system of claim 17, wherein the processing unit further is to:
move non-infrequently-accessed data in the first region to the second region of the dynamic random access memory responsive to the second region having space available.

19. The system of claim 17, wherein the processing unit further is to:
move infrequently-accessed data from the second region to the non-volatile memory to empty the second region of data; and
reduce the configurable refresh rate to a second value less than the first minimum refresh rate responsive to emptying the second region of data.

20. The system of claim 17, further comprising:
a non-transitory computer readable medium to store a set of executable instructions, the set of executable instructions to manipulate the processing unit to exchange the infrequently-accessed data, to move the data in the second region, and to reduce the configurable refresh rate.
